(19) United States
(12) Patent Application Publication
(10) Pub. No.: US 2007/0048906 A1
(43) Pub. Date: Mar. 1, 2007

(54) Method for fabricating semiconductor device

(76) Inventor: Seung Ho Han, Yongin-city (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 11/210,464

(22) Filed: Aug. 23, 2005

(51) Int. Cl. H01L 21/8232; H01L 21/8234; H01L 21/336; H01L 21/76

(52) U.S. Cl. 438/142; 438/197; 438/308; 438/428; 257/E21.12

(57) ABSTRACT

A method for fabricating a semiconductor device is disclosed in which a doping depth of an ion implanted dopant is prevented from being increased during annealing, so as to form a junction having a depth of 20 nm or below without any problem in the technology of 65 nm or below. The method includes the steps of a) implanting ions into a silicon substrate provided with a predetermined structure, b) applying tensile stress to a surface of the substrate, and c) annealing the substrate.

### BACKGROUND OF THE INVENTION

1. Field of the Invention

The present invention relates to a method for fabricating a semiconductor device, and more particularly, to a method for fabricating a semiconductor device in which a doping depth of an ion implanted dopant is prevented from being increased during annealing, so as to form a junction having a depth of 20 nm or below without any problem in the technology of 65 nm or below.

2. Discussion of the Related Art

Conventionally, an example of an annealing method includes soak annealing. The soak annealing has limitation in the technology of 130 nm. To solve such limitation, various annealing methods have been suggested. Of them, only spike annealing can commercially be used.

Unlike the existing annealing methods, the spike annealing has the relatively short annealing time and a relatively high annealing temperature. Generally, the spike annealing has a temperature of 1050° C. or greater. However, the soak annealing has a temperature of 1020° C. or below.

The spike annealing is more suitable for the technology of 130 nm or below than the soak annealing. The reasons are as follows.

Annealing is to remove a defect occurring during ion implantation and activate an ion implanted dopant. In this regard, it is noted that silicon interstitial atoms occur during ion implantation. The silicon interstitial atoms accompany some of the dopant during diffusion to cause transient enhanced diffusion (TED) that increases a doping depth.

Upon comparing diffusion coefficients between a soak annealing temperature and a spike annealing temperature, the diffusion coefficient of the dopant has no great difference in both soak annealing and spike annealing but the diffusion coefficient of the silicon interstitial atoms in the spike annealing is 1.5 times greater than that in the soak annealing. Therefore, when annealing is performed at a high temperature in the same manner as the spike annealing, the diffusion speed of the silicon interstitial atoms increases greater than that of the dopant. As a result, a defect occurring during ion implantation is removed even in case of annealing for a very short time (0.1 second or below), and diffusion of the dopant is performed without TED. Consequently, the spike annealing effectively removes the defect caused by ion implantation and reduces the diffusion distance of the dopant.

However, in spite of the aforementioned advantages, the spike annealing has limitation. In other words, the dopant increases at an amount of 10¹⁴ atom/cm² or greater. If ion implantation is performed at 1 KeV or below to reduce the doping depth, the density of the defect is high. For this reason, diffusion of the silicon interstitial atoms accompanying the dopant, i.e., TED occurs in the spike annealing. In this regard, a junction depth that can be obtained by the spike annealing is known as 25 nm or greater.

### SUMMARY OF THE INVENTION

Accordingly, the present invention is directed to a method for fabricating a semiconductor device that substantially obviates one or more problems due to limitations and disadvantages of the related art.

An object of the present invention is to provide a method for fabricating a semiconductor device, in which a doping depth of an ion implanted dopant is prevented from being increased during annealing, so as to form a junction having a depth of 20 nm or below required in the technology of 65 nm or below without any problem.

Another object of the present invention is to provide a method for fabricating a semiconductor device, in which a diffusion direction of silicon interstitial atoms, which is a main factor of TED, is guided to a surface direction to fundamentally avoid increase of a doping depth of a dopant.

Other object of the present invention is to provide a method for fabricating a semiconductor device, in which a thin film is effectively deposited on an ion implanted surface to apply compressed stress between ion implantation and annealing.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method for fabricating a semiconductor device includes the steps of a) implanting ions into a silicon substrate provided with a predetermined structure, b) applying tensile stress to a surface of the substrate, and c) annealing the substrate.

Preferably, the step b) includes depositing a thin film to which compressed stress is applied on the surface of the substrate.

Preferably, the thin film is deposited by a plasma chemical vapor deposition method.

Preferably, the thin film is a nitride or an oxide.

Preferably, the thin film has a thickness of 4 nm to 100 nm.

Preferably, the step c) is performed by spike rapid thermal annealing.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 to FIG. 2 illustrate process steps of fabricating a semiconductor device according to the present invention; and

FIG. 3 is a flow chart illustrating a method for fabricating a semiconductor device according to the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

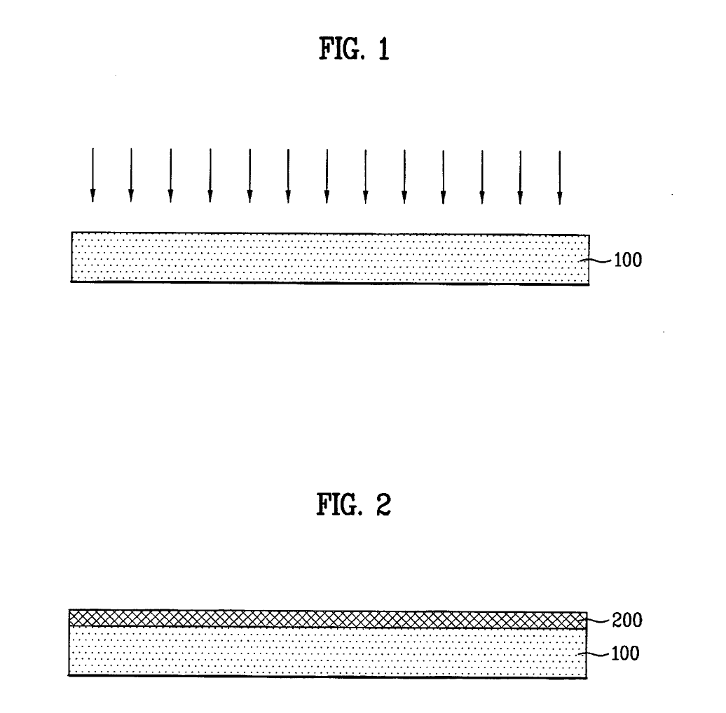

FIG. 1 is a process view illustrating ion implantation into a silicon substrate 100 provided with a predetermined structure (not shown). For example, lightly doped drain (LDD) ion implantation is performed on the substrate 100 or ion implantation for source and drain is performed on the substrate 100 where a gate is formed to form a channel. To make a doping depth thin during ion implantation, ion implantation is performed at a depth of several nm.

FIG. 2 is a process view illustrating deposition of a thin film 200 of an oxide or nitride on the substrate 100 where ion implantation is completed. The thin film 200 of an oxide or nitride is deposited on the substrate to generate compressed stress using a PE-CVD method. If the thin film 200 to which compressed stress is applied is deposited on the substrate 100, tensile stress is applied to the substrate 100.

In this way, if tensile stress is applied to the substrate 100, the distance between silicon interstitial atoms that are materials of the substrate 100 increases, so that the silicon interstitial atoms tend to move to a direction in which the distance between the atoms is great within a crystal, i.e., a surface of the substrate 100.

Therefore, if annealing is performed in a state that the thin film 200 to which compressed stress is applied is deposited on the substrate 100, the silicon interstitial atoms move to the surface of the substrate 100. As a result, a diffusion direction of the silicon interstitial atoms, which is a main factor of TED, is guided to a surface direction of the substrate 100 to fundamentally avoid increase of a doping depth of the ion implanted dopant.

Since the doping depth is determined by diffusion of the dopant, a junction depth of 10 nm can be obtained. Also, a junction that is available for 35 nm technology as well as 65 nm technology can be formed.

Meanwhile, it is preferable that the nitride to which compressed stress is applied is a PE-nitride, and that the oxide to which compressed stress is applied is a PE-TEOS when considering the relation between a defect occurring on the surface of the substrate 100 due to ion implantation and a structure of a spacer.

Preferably, the oxide or the nitride is deposited on the substrate 100 at a temperature of 400° C. to 500° C. using a PE-CVD process.

Further, the thin film 200 of the oxide or the nitride deposited on the substrate 100 by the PE-CVD process preferably has a thickness of 4 nm to 100 nm. This is because that the thin film 200 may affect a channel if it has a thickness of 100 nm or greater.

Annealing is performed on the substrate 100 where the oxide or nitride thin film 200 is deposited. Such an annealing process is preferably performed using spike rapid thermal annealing. The spike rapid thermal annealing is performed under the conditions including a temperature of 1050° C. or greater, time of 0.1 sec or below, a heating rate of 150° C./sec or greater, and a cooling rate of 70° C./sec or greater.

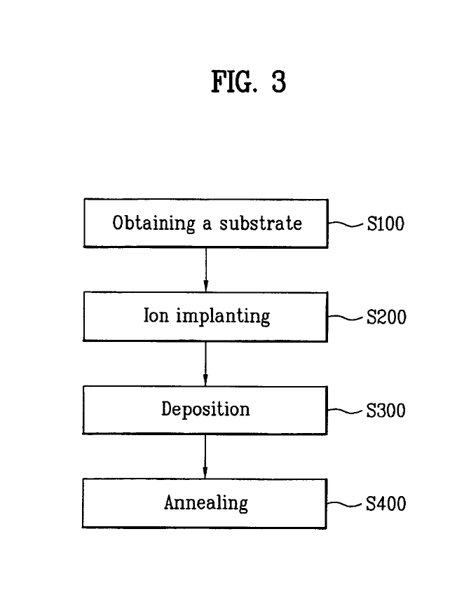

FIG. 3 is a flow chart illustrating a method for fabricating a semiconductor device according to the present invention.

As shown in FIG. 3, the method includes obtaining a silicon substrate provided with a predetermined structure (S100), implanting ions into the substrate (S200), depositing a nitride or an oxide, to which compressed stress is applied, on the substrate (S300), and annealing the substrate (S400).

As described above, the method for fabricating a semiconductor device according to the present invention has the following advantages.

The doping depth can be reduced for all cases where doping is performed by ion implantation and annealing. Also, the diffusion direction of the silicon interstitial atoms, which is a main factor of TED, is guided to the surface direction of the substrate to fundamentally avoid increase of the doping depth of the ion implanted dopant. Thus, it is possible to form the junction having a depth of 20 nm or below required in the technology of 65 nm or below.

Further, since the existing technologies for mass production, such as ion implantation and spike rapid thermal annealing, can be used as they are, it is possible to reduce the time for technology development, the cost for technology development, and the cost for production.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A method for fabricating a semiconductor device comprising the steps of:
a) implanting ions into a silicon substrate provided with a predetermined structure;
b) applying tensile stress to a surface of the substrate; and
c) annealing the substrate by spike rapid thermal annealing.

2. The method according to claim 1, wherein the step b) includes depositing a thin film to which compressed stress is applied on the surface of the substrate.

3. The method according to claim 2, wherein the thin film is deposited by a plasma enhanced chemical vapor deposition (PE-CVD) method

4. The method according to claim 3, wherein the PE-CVD method is performed at a temperature of 400° C. to 500° C.

5. The method according to claim 2, wherein the thin film comprises a PE-nitride.

6. The method according to claim 2, wherein the thin film has a thickness of 4 nm to 100 nm

7. (canceled)

8. The method according to claim 1, wherein the spike rapid thermal annealing is performed under conditions including a temperature of 1050° C. or greater, time of 0.1 sec or below, a heating rate of 150° C./sec or greater, and a cooling rate of 70° C./sec or greater.

9. The method according to claim 2, wherein the thin film comprises PE-TEOS.

10. The method according to claim 1, wherein the spike rapid thermal annealing is performed at a temperature of 1050° C. or greater.

11. The method according to claim 10, wherein the spike rapid thermal annealing is performed for a time of 0.1 sec or below.

12. The method according to claim 11, wherein the spike rapid thermal annealing is preformed at a heating rate of 150° C./sec or greater.

13. The method according to claim 10, wherein the spike rapid thermal annealing is performed at a heating rate of 150° C./sec or greater.

14. The method according to claim 13, wherein the spike rapid thermal annealing is preformed at a cooling rate of 0° C./sec or greater.

15. The method according to claim 1, wherein the spike rapid thermal annealing is performed for a time of 0.1 sec or below.

16. The method according to claim 15, wherein the spike rapid thermal annealing is performed at a heating rate of 150° C./sec or greater.

17. The method according to claim 16, wherein the spike rapid thermal annealing is performed at a cooling rate of 70° C./sec or greater.

18. The method according to claim 1, wherein the spike rapid thermal annealing is performed under conditions including a heating rate or 150° C./sec or greater and a cooling rate of 70° C./sec or greater.

19. The method according to claim 1, wherein implanting the ions forms a source and a drain.

20. The method according to claim 1, wherein implanting the ions forms lightly doped drain (LDD) regions.
